(19) United States
(12) Patent Application Publication
(10) Pub. No.: US 2023/0120584 A1
(43) Pub. Date: Apr. 20, 2023

(54) MULTIPLE ANTENNAS IN A MULTI-LAYER SUBSTRATE

(71) Applicant: TEXAS INSTRUMENTS INCORPORATED, Dallas, TX (US)

(72) Inventors: Hassan Ali, Murphy, TX (US); Richard Wallace, Stockholm (SE); Swaminathan Sankaran, Allen, TX (US)

(21) Appl. No.: 17/876,449

(22) Filed: Jul. 28, 2022

Related U.S. Application Data
(60) Provisional application No. 63/257,057, filed on Oct. 18, 2021.

(51) Int. Cl. H01Q 1/22; H05K 1/02; H01L 23/66

(52) U.S. Cl. CPC H01Q 1/2283; H05K 1/0243; H01L 23/66; H05K 2201/10098; H01L 2223/6616; H01L 2223/6677

(57) ABSTRACT

In one example, an apparatus comprises an integrated circuit, a first metal layer, and a second metal layer. The first metal layer includes a first antenna connected to the integrated circuit, the first antenna being in a first region, the first region being external to the integrated circuit. The second metal layer includes a second antenna in a second region external to the integrated circuit. The apparatus further comprises a substrate between the first and second metal layers, in which the substrate and the first and second metal layers form a laminate. The apparatus further comprises a through-via in the substrate that couples between the first and second antennas.

### CROSS-REFERENCE TO RELATED APPLICATION

This application claims priority to U.S. Provisional Patent Application No. 63/257,057 filed Oct. 18, 2021, which is hereby incorporated herein by reference.

### BACKGROUND

A portable wireless device, such as a laptop computer, a mobile phone, or a smart watch, includes multiple electronic components mounted on a substrate, such as a printed circuit board, which provides mechanical support, and includes metal traces to provide electrical connectivity among the electronic components. The wireless device also includes an antenna that operates with transceiver to transmit/receive radio frequency (RF) signals, to support wireless communication with other devices. To reduce the footprint and the number of electronic components of the wireless device, the antenna can be implemented with the metal traces of the PCB. Various factors can affect the performance characteristics of the antenna, such as the antenna topology, the dimensions of the antenna, the location of the antenna, and the connection between the antenna and the transceiver.

### SUMMARY

An apparatus comprises an integrated circuit, a first metal layer, and a second metal layer. The first metal layer includes a first antenna connected to the integrated circuit, the first antenna being in a first region, the first region being external to the integrated circuit. The second metal layer includes a second antenna in a second region external to the integrated circuit. The apparatus further comprises a substrate between the first and second metal layers, in which the substrate and the first and second metal layers form a laminate. The apparatus further comprises a through-via in the substrate that couples between the first and second antennas.

### BRIEF DESCRIPTION OF THE DRAWINGS

FIG. 1 is a schematic of an example wireless system.

FIG. 2A and FIG. 2B are schematics of another example wireless system.

FIG. 3 is a graph of the frequency response of the example wireless system of FIGS. 2A and 2B.

FIGS. 4A to 4C are schematics of an example wireless system having multiple antennas in multiple metal layers of a laminated substrate.

FIG. 4D is a graph of the frequency response of the example wireless system of FIGS. 4A to 4C.

FIG. 5 is a schematic of another example wireless system having multiple antennas in multiple metal layers of a laminated substrate.

FIGS. 6A to 6C are schematics of another example wireless system having multiple antennas in multiple metal layers of a laminated substrate.

FIG. 7 is a graph of the frequency response of the example wireless system of FIGS. 6A to 6C.

FIGS. 8 to 10 are schematics of example wireless system having multiple antennas in multiple metal layers of a laminated substrate.

FIG. 11 is a graph of the frequency response of the example wireless system of FIGS. 8 to 10.

### DETAILED DESCRIPTION

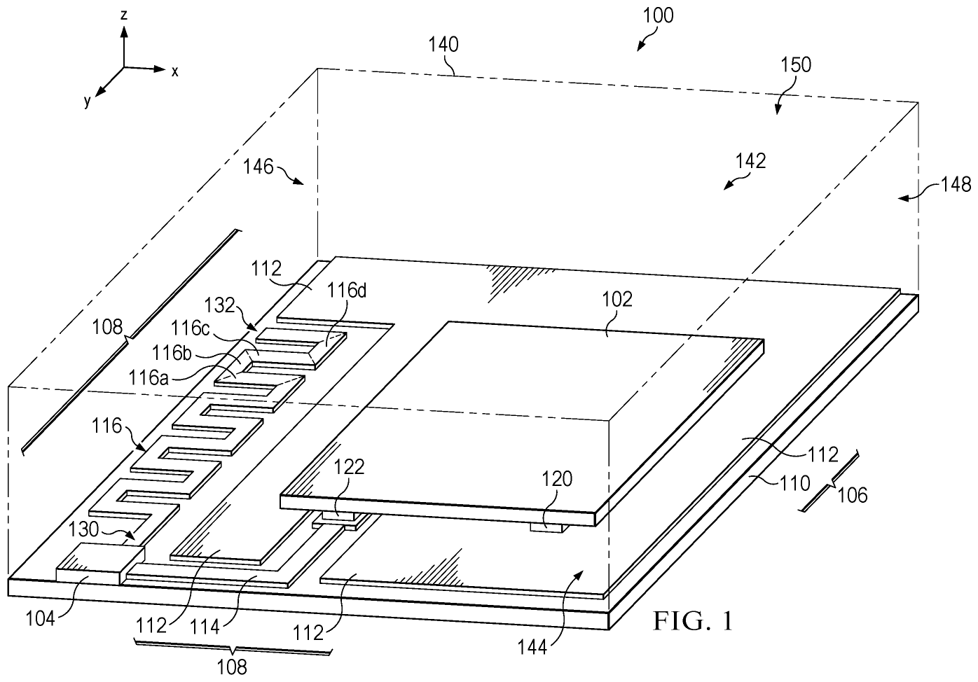

FIG. 1 is a schematic of an example wireless system 100, which can be part of an integrated circuit. Wireless system 100 can include a semiconductor die 102 and an impedance matching circuit 104 mounted on a substrate 106. Substrate 106 can include a metal layer 108 on a dielectric layer 110. Metal layer 108 can include a metal plane 112, a metal segment 114, and a metal segment 116, which can provide an antenna of wireless system 100. Metal plane 112 can provide a much wider current path than metal segments 114 and 116, and can be part of a ground plane coupled to a metal interconnect 120 of semiconductor die 102. Also, metal segment 114 can be a segment coupled between impedance matching circuit 104 and another metal interconnect 122 of semiconductor die 102. Semiconductor die 102 can include a transceiver circuit coupled to metal interconnect 122 to transmit/receive RF signals via the antenna, and metal segment 114 can be the feed line for the antenna.

Impedance matching circuit 104 can include an alternating current (AC) capacitor with a first plate coupled to metal segment 114 and a second plate coupled to metal segment 116. The impedance of the AC capacitor can be combined with the impedance of metal segment 116/antenna. The combined impedance can be tuned by selecting/configuring the capacitance of the AC capacitor to match with the impedance of metal segment 114. The matching of the impedances can improve the power transfer between the transceiver circuit and the antenna and improve the wireless system's overall sensitivity and efficiency. For example, metal segment 116 can present an impedance of R_{L}+jX_{L} where R_{L} and X_{L} represent the respective resistance and reactance components of the impedance of metal segment 116. Also, the transceiver circuit can present an impedance of R_{S}+jX_{S} where R_{S} and X_{S} represent the respective resistance and reactance components of the impedance of the transceiver circuit. To maximize (or at least to increase) the power transfer between the transceiver circuit and the antenna, impedance matching circuit 104 can transform the impedance of metal segment 116 into a complex conjugate of the impedance of the transceiver circuit, which is R_{S}−jX_{S}.

To improve the radiation resistance, bandwidth, and efficiency of the antenna, the electrical path provided by metal segment 116 can be extended. To reduce the footprint of the electrical path, metal segment 116 can include multiple subsegments (e.g., 116a, 116b, 116c, and 116d) joined together, where adjoining subsegments (e.g., 116a and 116b, 116b and 116c) are angled (e.g., 90 degrees) from each other and form a meander metal segment, and the antenna can be a meander antenna. A first end 130 of metal segment 116 can be coupled to impedance matching circuit 104, and a second end 132 of metal segment 116 can be an open/disconnected end. In some examples, second end 132 of metal segment 116 can be coupled to metal plane 112, and metal segment 116 can form a loop antenna.

Also, semiconductor die 102, impedance matching circuit 104, and metal layer 108 can be encapsulated in an encapsulation package 140. Encapsulation package 140 can be made of a mold compound (e.g., plastic or resin) to provide electrical insulation between metal plane 112 and metal segments 114 and 116, and between metal interconnects of semiconductor die 102. Also, the surfaces of encapsulation package 140, including surfaces 142 and 144 (parallel with x-z plane), surfaces 146 and 148 (parallel with z-y plane), and surface 150 (parallel with the x-y plane), can be coated with a layer of metal. The coating can be performed by a full surface metal sputtering process. The metal layer can shield semiconductor die 102 and impedance matching circuit 104 from unwanted RF signals, such as radiations, or other out-of-band RF signals.

Although the metal layer on surfaces 142 through 150 can shield the electronic components in encapsulation package 140 from radiations or other unwanted RF signals, the metal layers can also shield metal segment 116 and prevent metal segment 116 from receiving or transmitting RF signals out of encapsulation package 140. One way to reduce the shielding effect of the metal layer on the antenna is by coating only part of the surfaces 142 through 150 with the metal layer. For example, in FIG. 1, surface 146 and part of surfaces 142, 144, and 150 that proximate metal segment 116 may be uncoated, to provide an opening through which the antenna can receive or transmit RF signals out of encapsulation package 140. A partial surface metal sputtering process can be performed to coat part of the surfaces 142 through 150 with the metal layer. But such arrangements may also allow unwanted RF signals to enter encapsulation package 140 through and degrade the shielding effect. Also, the limited precision of the partial surface metal sputtering process may introduce variations in the size and location of the opening, which can increase the performance uncertainties of the antenna and the overall wireless system 100.

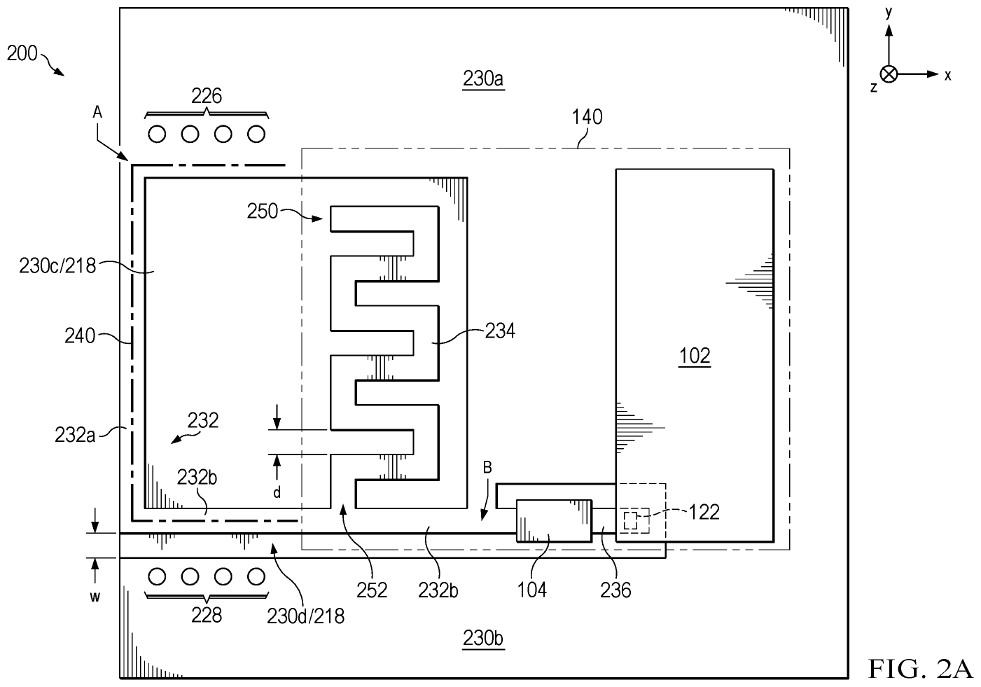

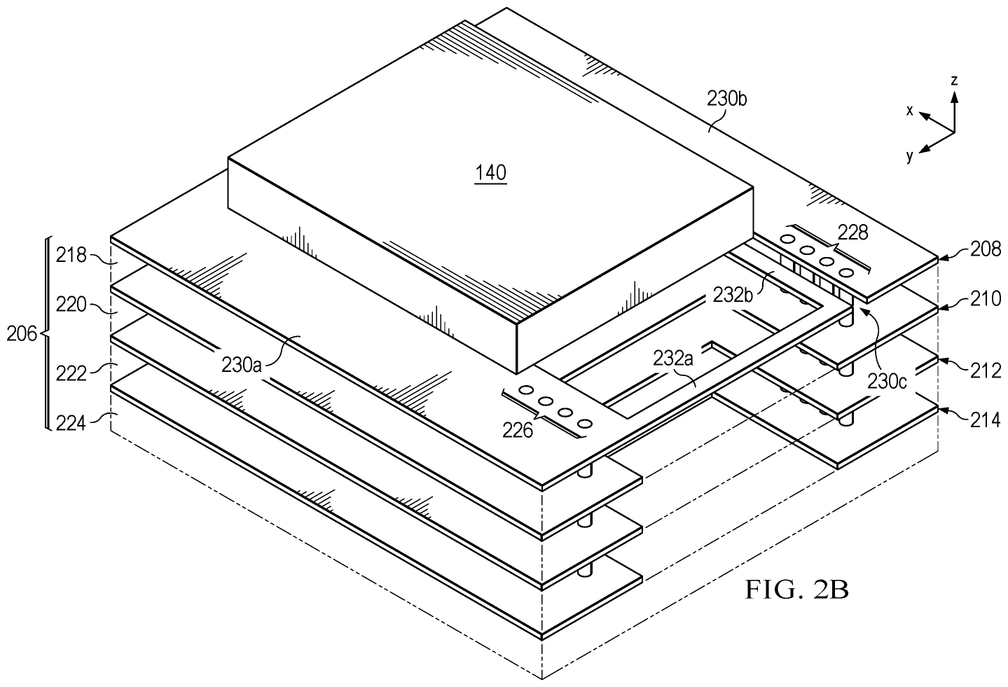

FIG. 2A and FIG. 2B are schematics of another example wireless system 200. FIG. 2A illustrates a top view, and FIG. 2B illustrates a perspective view. Wireless system 200 can include semiconductor die 102 and impedance matching circuit 104 mounted on a substrate 206, and semiconductor die 102 and impedance matching circuit 104 can be encapsulated in encapsulation package 140. Referring to FIG. 2A and FIG. 2B, substrate 206 can include multiple metal layers such as metal layers 208, 210, 212, and 214, and multiple dielectric layers such as dielectric layers 218, 220, 222, and 224 forming a laminated substrate 206. Substrate 206 can also include through-vias 226 and 228 that penetrate through the multiple metal layers and dielectric layers, to provide electrical connection among the multiple metal layers. In some examples, substrate 206 can include a multi-layer printed circuit board (PCB), the metal layers can include copper layers, and the dielectric layers can include an epoxy material. In some examples, substrate 206 can also include multiple PCBs laminated together. For example, metal layer 208 and dielectric layer 218 can be of a first PCB, metal layer 210 and dielectric layer 220 can be of a second PCB, metal layer 212 and dielectric layer 222 can be of a third PCB, and metal layer 214 and dielectric layer 224 can be of a fourth PCB.

Also, metal layer 208 can include a metal plane 230, which can include plane regions 230a and 230b, and a separation area 230c between plane regions 230a and 230b that exposes dielectric layer 218. Separation area 230c can be filled with an insulation material, such as dielectric and air. Metal layer 208 can also include metal segments 232, 234, and 236. Metal segment 232 can include subsegment 232a and 232b. Subsegment 232a can extend out of a first part of plane region 230a (marked “A” in FIG. 2A) not overlaid with encapsulation package 140. Subsegment 232b extends from and is angled relative to subsegment 232a. Subsegment 232b can extends into a second part of plane region 230a (labelled “B” in FIG. 2A) and couples with impedance matching circuit 104. Subsegment 232b can be spaced from plane region 230b by separation area 230c. Plane region 230a and metal segment 232 can provide a loop antenna 240, which can conduct a current around the loop responsive to detecting an RF signal or to transmit/radiate an RF signal, and part of metal subsegment 232b can provide a feed line for the loop antenna. Loop antenna 240 can be in an external region adjacent to encapsulation package 140. Accordingly, loop antenna 240 is less obstructed by encapsulation package 140, which allows loop antenna 240 to transmit and receive RF signals.

Metal segment 234 can also include a meander segment having a first end 250 disconnected/separated from plane region 230a and forming a disconnected/open end. The meander segment also has a second end 252 that connects with subsegment 232b. Meander metal segment 234 can provide an inductive loading, which can be tuned by varying the length of metal segment 234 and the spacing (labelled “d” in FIG. 2A) between the meander subsegments. Also, there can be a gap 230d between subsegment 232b and plane region 230b to provide capacitive loading, which can be tuned by varying the width of gap 230d (labelled “w” in FIG. 2A). Gap 230d can be filled with an insulation material, such as dielectric and air. The inductive and capacitive loading, combined with impedance matching circuit 104, can be configured to tune the impedance of the feed line of loop antenna 240 to match with the impedance of semiconductor die 102 (represented by the impedances of metal segment 236 and metal interconnect 122). The matching of the impedances can improve the power transfer between the transceiver circuit and the antenna, and improve the antenna's overall sensitivity and efficiency.

Although loop antenna 240 in wireless system 200 of FIG. 2 can receive or transmit RF signals unobstructed (or with less obstruction) by encapsulation package 140, various factors can limit its performance. Specifically, the resonance of loop antenna 240 is narrowband, and loop antenna 240 may have a narrow bandwidth for transmitting/detecting RF signals. For example, loop antenna 240 may have a bandwidth between 5 to 10 MegaHertz (MHz). The narrow bandwidth may be inadequate for many wireless applications, for which the antenna may transmit/receive RF signals over a bandwidth wider than 5 to 10 MHz.

Also, the loop size of loop antenna 240 may be shrunk (e.g., by reducing the lengths of subsegments 232a and 232b) to reduce the overall footprint of wireless system 200, because loop antenna 240 is in an external region adjacent to encapsulation package 140 and adds to the footprint of wireless system 200. But shrinking the loop size can reduce the radiation efficiency and gain of loop antenna 240. This can reduce the power of the RF signals transmitted or received by loop antenna 240 and reduce the transmission/detection range of the antenna. The overall sensitivity and efficiency of wireless system 200 can be further reduced due to the increased inductance of the antenna loop, which makes it difficult to match the impedances between the antenna loop and semiconductor die 102.

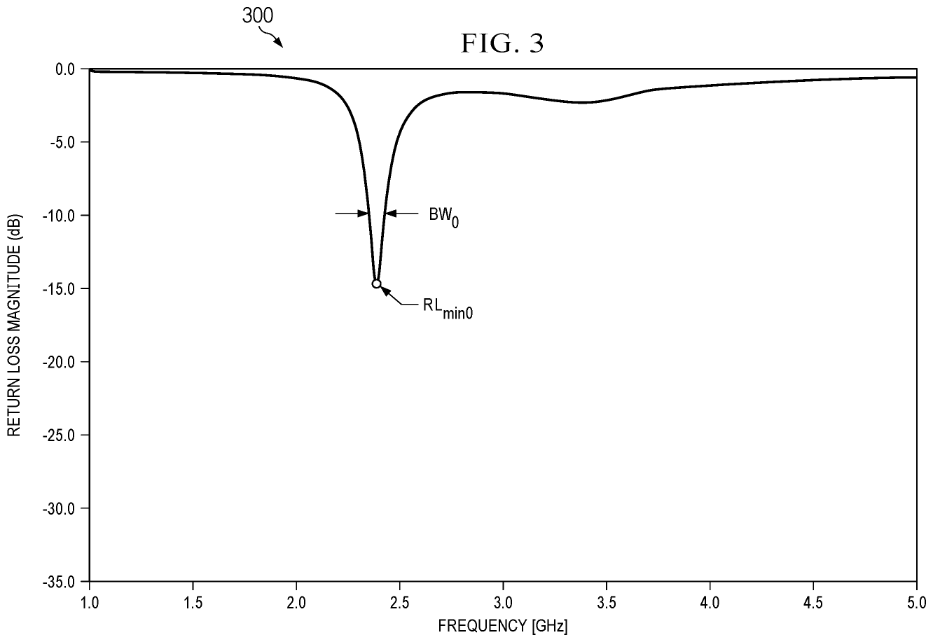

FIG. 3 is a graph 300 of the variation of return loss (RL) of loop antenna 240 of FIG. 2A and FIG. 2B with respect to frequency. In FIG. 3 and for the rest of the disclosure, the return loss can be a ratio between an amount of power reflected/rejected by loop antenna 240 (Pᵣ) and an amount of power provided to loop antenna 240 (Pᵢ). In a case where loop antenna 240 transmits RF signals, Pᵢ can refer to the amount of power provided to loop antenna 240 by semiconductor die 102. In a case where loop antenna 240 detects RF signals, Pᵢ can refer to the amount of power detected by loop antenna 240. RL can be given by the following Equation:

$$RL = 10 {log}_{10} \frac{{P}_{r}}{{P}_{i}} \qquad ( Equation 1 )$$

Referring to FIG. 3, loop antenna 240 provides a resonant system and can reject RF signals within frequency bands between 1-2 GigaHertz (GHz) and between 2.7 to 5 GHz, where the return loss is close to 1. Loop antenna 240 can transmit/receive RF signals within a frequency band between 2-2.7 GHz. The bandwidth of loop antenna 240 can include a frequency range where the return loss is lower than −10 dB, which is labelled “BW₀” in FIG. 3 and is about 75 MHz. The resonant frequency of loop antenna 240 is at 2.4 GHz where the return loss is at a minimum level of −15 dB, labelled “RLₘᵢₙ₀” in FIG. 3. The narrow 75 MHz bandwidth of the loop antenna may be inadequate for many wireless applications.

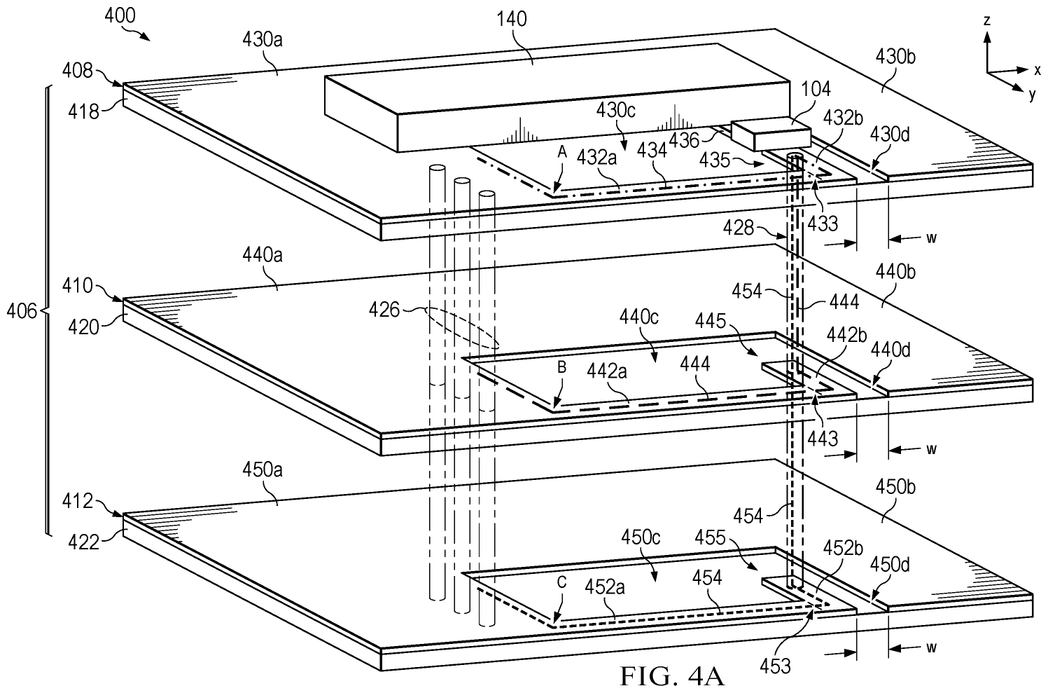

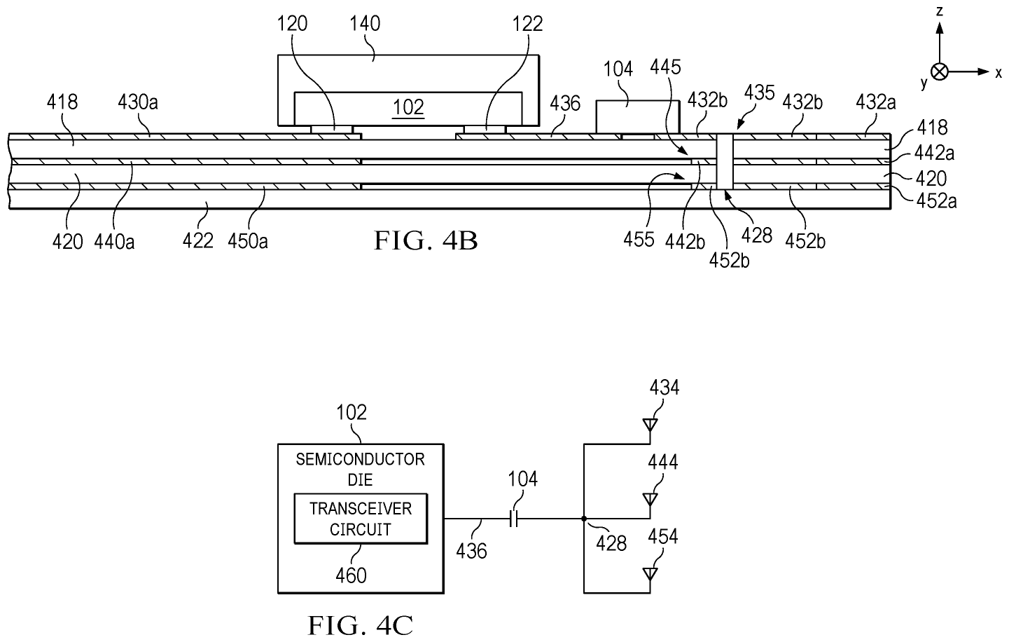

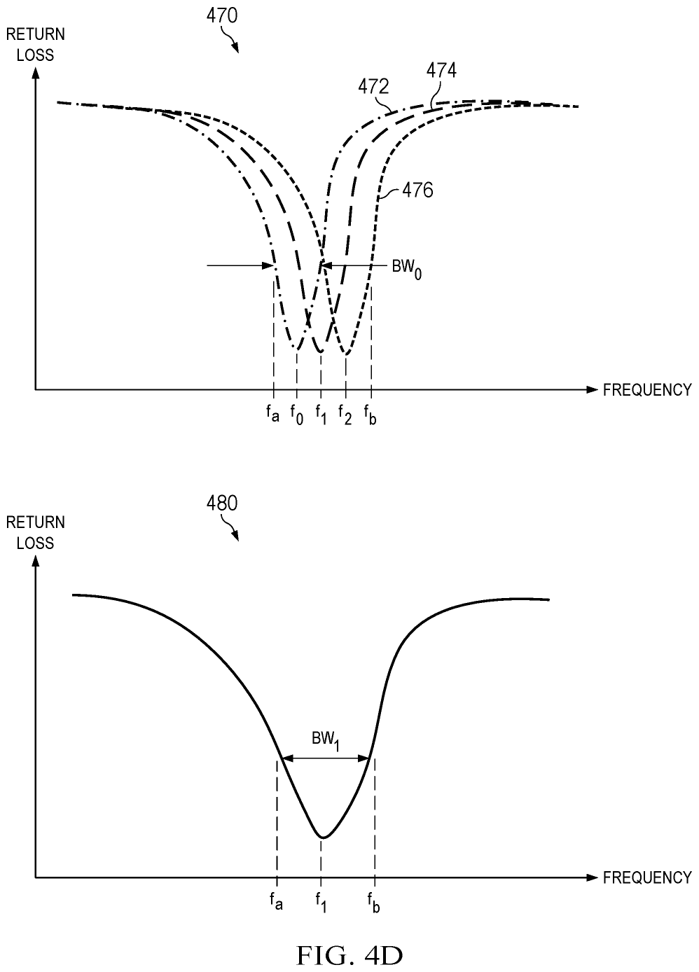

FIGS. 4A through 4D illustrate an example wireless system 400 that can address at least some of the issues described above. FIG. 4A is a schematic that illustrates a perspective and exploded view of wireless system 400, and FIG. 4B is a schematic that illustrates a partial side view of wireless system 400. Referring to FIG. 4A and FIG. 4B, wireless system 400 can include semiconductor die 102 and impedance matching circuit 104 mounted on a substrate 406, with at least semiconductor die 102 encapsulated in encapsulation package 140. Substrate 406 can include multiple metal layers, such as metal layers 408, 410, and 412, and multiple dielectric layers, such as dielectric layers 418, 420, and 422 laminated together forming a laminated substrate. Substrate 406 can also include through-vias 426 and 428 that extends through the multiple metal layers and dielectric layers, to provide electrical connection among the multiple metal layers. In some examples, substrate 406 can include a multi-layer PCB, the metal layers can include copper layers, and the dielectric layers can include an epoxy material. In some examples, substrate 406 can include multiple PCBs laminated together, where metal layer 408 and dielectric layer 418 can be of a first PCB, metal layer 410 and dielectric layer 420 can be of a second PCB, and metal layer 412 and dielectric layer 422 can be of a third PCB, and the PCBs can be stacked to form a laminated substrate 406.

Each metal layer can include a metal plane and a metal segment, with the metal segment extending out of a first part of the metal plane and back into a second part of the same metal plane and form a loop antenna. Specifically, metal layer 408 can include a metal plane 430, which includes plane regions 430a and 430b, and a separation area 430c between plane regions 430a and 430b that exposes dielectric layer 418. Separation area 430c can be filled with an insulation material, such as dielectric and air. Metal plane 430 can be coupled to a voltage source and configured as a ground plane. Metal layer 408 can also include metal segment 432, which includes metal subsegments 432a and 432b. Metal subsegment 432a can extend from a part of plane region 430b (labelled “A” in FIG. 4A). Metal subsegment 432b can extend from an end 433 of metal subsegment 432a and is angled relative to metal subsegment 432a, and metal subsegment 432b can be coupled to impedance matching circuit 104 at end 435. Through-via 428 extends through metal subsegment 432b and is more proximate to end 435 than to metal subsegment 432a. Metal segment 432 435 can provide a loop antenna 434, which is spaced from encapsulation package 140 by separation area 430c. Loop antenna 434 can conduct a current through an edge of plane region 430a, and through metal segment 432, to reach impedance matching circuit 104 in response to detecting a RF signal, or to transmit an RF signal. Metal layer 408 can also include a metal segment 436 that couples between impedance matching circuit 104 and semiconductor die 102 to conduct the current between them. Metal subsegment 432b can also be spaced from plane region 430b by a gap 430d. Gap 430d can be filled with an insulation material, such as dielectric and air, and can provide a capacitive loading which, combined with the AC capacitance of impedance matching circuit 104, can set the impedance of loop antenna 434 to match with metal segment 436. The capacitive loading can be set by the width (labelled “w” in FIG. 4A) of gap 430d.

Also, metal layer 410 can include a metal plane 440, which includes plane regions 440a and 440b, and a separation area 440c between plane regions 440a and 440b that exposes dielectric layer 420. Separation area 440c can be filled with an insulation material, such as dielectric and air. Metal plane 440 can be coupled to metal plane 430 by through-vias 426 and configured as a ground plane. Metal layer 410 can also include metal segment 442, which includes metal subsegments 442a and 442b. Metal subsegment 442a can extend from a part of plane region 440a (labelled “B” in FIG. 4A). Metal subsegment 442b can extend from an end 443 of metal subsegment 442a and is angled relative to metal subsegment 442a, and metal subsegment 442b can have an end 445 detached/separated from metal plane 440 to form an open/disconnected end. Through-via 428 extends through metal subsegment 442b to provide electrical connection between metal segments 432 and 442, and is more proximate to end 445 than to metal subsegment 442a. Metal segment 442, 445 together with through-via 428 between metal layers 408 and 410, can provide a loop antenna 444, which is spaced from encapsulation package 140 by separation area 440c. Loop antenna 444 can conduct a current through an edge of plane region 440a, through metal segment 442, and through through-via 428 between metal layers 408 and 410 to reach impedance matching circuit 104 and semiconductor die 102 in response to detecting an RF signal, or to transmit an RF signal. Metal subsegment 442b can also be spaced from plane region 440b by a gap 440d. Gap 440d can be filled with an insulation material, such as dielectric and air, and can provide a capacitive loading which can set the impedance of loop antenna 444 to match with metal segment 436. The capacitive loading can be set by the width (labelled “w” in FIG. 4A) of gap 440d.

Further, metal layer 412 can include a metal plane 450, which includes plane regions 450a and 450b, and a separation area 450c between plane regions 450a and 450b that exposes dielectric layer 422. Separation area 450c can be filled with an insulation material, such as dielectric and air. Metal plane 450 can be coupled to metal planes 430 and 440 by through-vias 426 and configured as a ground plane. Metal layer 412 can also include metal segment 452, which includes metal subsegments 452a and 452b. Metal subsegment 452a can extend from a part of plane region 450a (labelled “C” in FIG. 4A). Metal subsegment 452b can extend from an end 453 of metal subsegment 452a and is angled relative to metal subsegment 452a, and metal subsegment 452b can have an end 455 detached/separated from metal plane 450 to form an open/disconnected end. Through-via 428 extends through metal subsegment 452b to provide electrical connection among metal segment 452 and metal segments 432 and 442, and is more proximate to end 455 than to metal subsegment 452a. Metal segment 452, together with through-via 428 between metal layers 408 and 412, can provide a loop antenna 454. Loop antenna 454 can conduct a current through an edge of plane region 450a, through metal segment 452, and through through-via 428 between metal layers 408 and 412 to reach impedance matching circuit 104 and semiconductor die 102 in response to detecting an RF signal, or to transmit an RF signal. Metal subsegment 452b can be spaced from plane region 450b by a gap 450d that is part of separation area 450c. Gap 450d can be filled with an insulation material, such as dielectric and air, and can provide a capacitive loading which can set the impedance of loop antenna 454 to match with metal segment 436. The capacitive loading can be set by the width (labelled “w” in FIG. 4A) of gap 450d.

With the example arrangements of FIGS. 4A-4C, three loop antennas 434, 444, and 454 can be coupled to impedance matching circuit 104 and semiconductor die 102 by through-via 428. The connectivity among loop antennas 434, 444, and 454, impedance matching circuit 104, and semiconductor die 102 are represented in a circuit schematic in FIG. 4C. Referring to FIG. 4C, metal segment 436 is coupled between a transceiver circuit 460 of semiconductor die 102 and one side of a capacitor of impedance matching circuit 104. Also, the other side of the capacitor of impedance matching circuit 104 is coupled with three loop antennas 434, 444, and 454 by through-via 428, which can provide the feed line to each of the three antennas. Accordingly, transceiver circuit 460 can use one or more three loop antennas 434, 444, and 454 to transmit and receive RF signals.

The multiple loop antennas 434, 444, and 454 can have similar frequency responses, which can be combined to widen the operational frequency range of wireless system 400. The radiation efficiency and gain of the combined antennas can also be increased over the frequency range.

FIG. 4D illustrates a chart 470 that includes graphs 472, 474, and 476 of the return loss of respective loop antennas 434, 444, and 454, and a chart 480 of the combined return loss of the three loop antennas. Referring to chart 470, loop antenna 434 can have a resonant frequency at f₀ where the return loss is at a minimum within the range of frequencies represented in FIG. 4D, loop antenna 444 can have a resonant frequency at f₁ where the return loss is at a minimum, and loop antenna 454 can have a resonant frequency at f₂ where the return loss is at a minimum. The loop antennas can have different resonant frequencies because they have different loop sizes. As described above, loop antenna 444 can include through-via 428 between metal layers 408 and 410, which extends the current path and increases the loop size of loop antenna 444. Also, loop antenna 454 can include through-via 428 between metal layers 408 and 412, which also extends the current path and increases the loop size of loop antenna 454. As each loop antenna has a different current path extension from through-via 428, they can have different loop sizes and different resonant frequencies.

Also, each loop antenna can have the same bandwidth (e.g., BW₀) centered around the respective resonant frequencies f₀, f₁, and f₂. While the resonant frequencies f₀, f₁, and f₂ are different, the differences are small so that the frequency responses of the loop antennas can be combined over a frequency range fₐ and f_{b} that includes resonant frequencies f₀, f₁, and f₂. Chart 480 represents the combined return loss of loop antennas 434, 444, and 454. Referring to chart 480, the combined bandwidth of antennas 434, 444, and 454 (labelled “BW₁”), which spans between frequency range fₐ to f_{b}, can be wider than the bandwidth BW₀ of each standalone antenna, which can widen the overall bandwidth of wireless system 400 in transmitting/detecting RF signals.

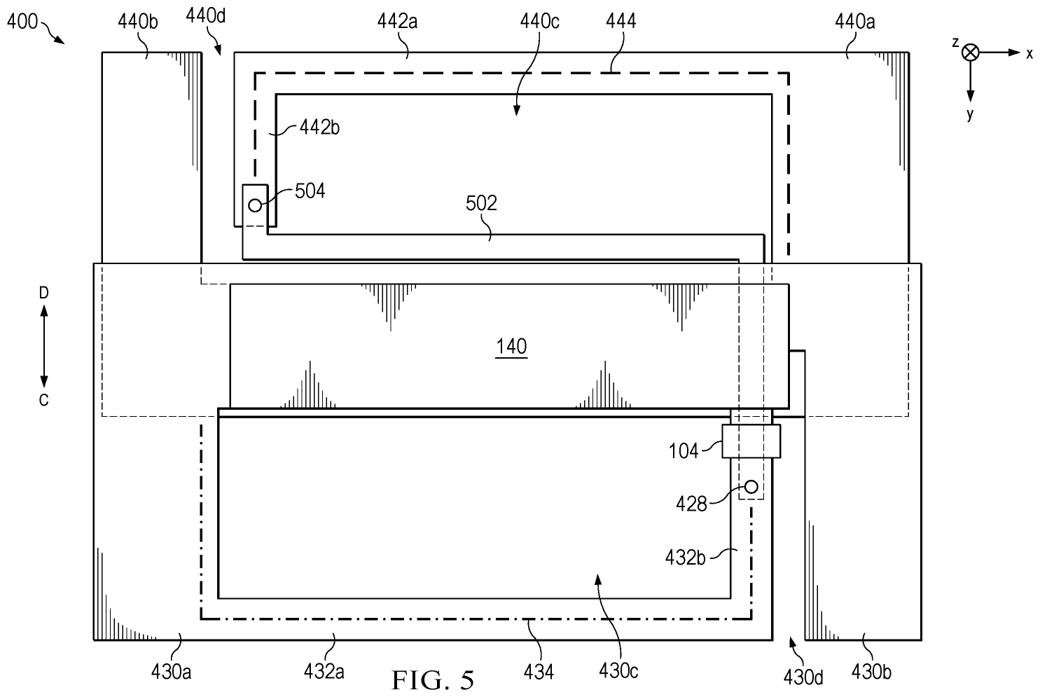

In the examples of FIGS. 4A through 4D, metal segment 432 of metal layer 408, metal segment 442 of metal layer 410, and metal segment 452 of metal layer 412 can be on the same side of encapsulation package 140, and loop antennas 434, 444, and 454 can form a stack (e.g., along the z-axis). In some examples, antennas in different metal layers can be on different sides of encapsulation package 140. FIG. 5 is a schematic of an example wireless system 400 having loop antennas 434 and 444 on different sides of encapsulation package 140. Referring to FIG. 5, plane regions 430a and 430b, separation area 430c, gap 430d, and metal subsegments 432a and 432b can be on a first side (e.g., direction C) of encapsulation package 140. Also, plane regions 440a and 440b, separation area 440c, gap 440d, and metal subsegments 442a and 442b can be on a second side (e.g., direction D) of encapsulation package 140. A different metal layer (e.g., metal layer 412) can include a metal segment 502 that couples between metal subsegment 442b and through-via 428, and metal segment 502 can be coupled to metal subsegment 442b by a through-via 504.

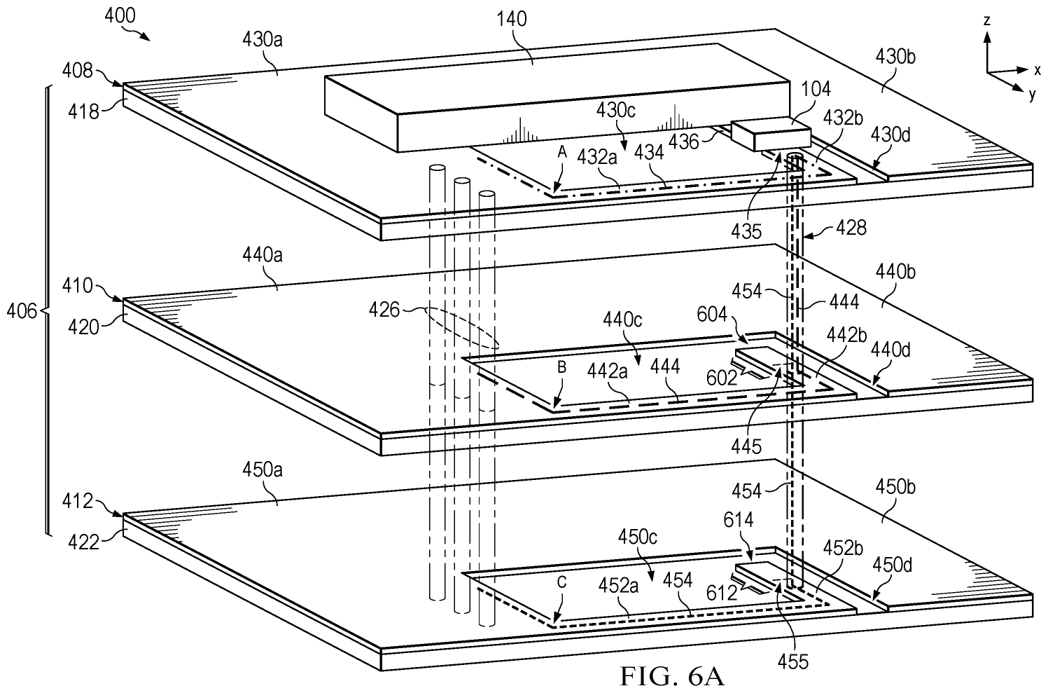

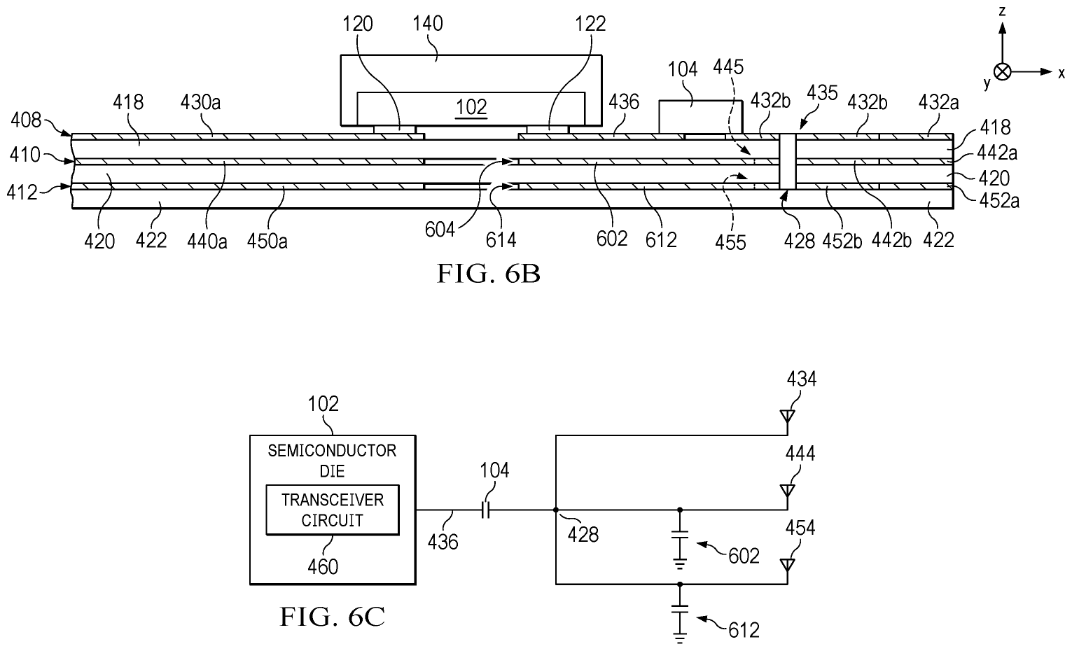

FIGS. 6A-6C illustrate another example wireless system 400. FIG. 6A is a schematic that illustrates a perspective and exploded view of wireless system 400, and FIG. 6B is a schematic that illustrates a partial side view of wireless system 400. Referring to FIG. 6A and FIG. 6B, metal segment 442 includes a metal subsegment 602 that extends from end 445 of metal subsegment 442b, which is more proximate to through-via 428 than metal subsegment 442a. Metal subsegment extension 602 has an open end 604 separated from metal plane 440. Also, metal segment 452 includes a metal subsegment extension 612 that extends from end 455 of metal subsegment 442b, which is more proximate to through-via 428 than metal subsegment 452a. Metal subsegment extension 612 has an open end 614 separated from metal plane 450. In the examples of FIGS. 6A and 6B, ends 445 and 455 can be imaginary ends for illustrative purpose, where metal subsegments 442b and 602 can be a continuous metal subsegment, and metal subsegments 452b and 612 can also be a continuous metal subsegment.

Each of metal subsegment extensions 602 and 612 can be an open stub, which can provide additional capacitive loading to respective metal segments 442 and 452, and to respective loop antennas 444 and 454. FIG. 6C is a circuit schematic representing loop antennas 434, 444, and 454, impedance matching circuit 104, semiconductor die 102, and the capacitive loading provided by metal subsegment extensions 602 and 612. Referring to FIG. 6C, metal segment 436 is coupled between transceiver circuit 460 of semiconductor die 102 and one side of a capacitor of impedance matching circuit 104. Also, the other side of the capacitor of impedance matching circuit 104 is coupled with three loop antennas 434, 444, and 454 by through-via 428 as the feed line. Also, metal subsegment extension 602 can provide a shunt capacitive loading between through-via 428 and antenna 444, and metal subsegment extension 612 can provide a shunt capacitive loading between through-via 428 and antenna 454.

The shunt capacitive loading can be configured to tune the impedances of respective loop antennas 444 and 454. For example, the capacitance of metal subsegment extension 602/612, Cₑₓₜ, can provide a reactance component that can be combined with the reactance component of the loop antennas 444/454 impedance to provide capacitive tuning. For example, the capacitance Cₑₓₜ can be tuned so that the combined impedance of loop antennas 444/454 and respective metal subsegment extension 602/612 can be equal to the complex conjugate of the impedance of the transmitter circuit to maximize power transfer.

The metal subsegment extensions 602 and 612, together with impedance matching circuit 104, can provide different options to tune the combined impedance of the loop antennas, to further improve the impedance matching between the feed line and metal segment 436 (and transceiver circuit 460), and to improve the power transfer between the transceiver circuit and the antenna. For example, the Cₑₓₜ can be set by the length (along the y-axis) and width (along the x-axis) of the metal subsegment extension. Also, in some examples, different loop antennas can have metal subsegment extensions of different lengths/widths to provide different capacitive loading. This can be because different loop antennas may have different loop sizes and can have different Cₛₕᵤₙₜ capacitance and different capacitive reactance. Accordingly, metal subsegment extensions 602 and 612 can have different dimensions to provide different Cₑₓₜ capacitances to combine with the different capacitive reactances of the respective loop antennas 444 and 454 to tune the combined impedance of the loop antennas.

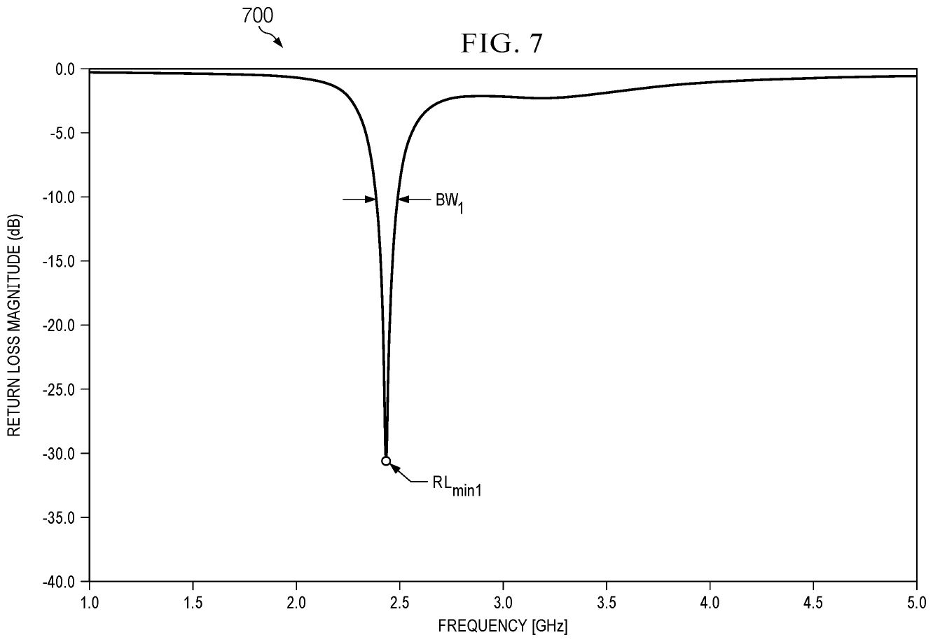

FIG. 7 is a graph 700 of the variation of the combined return loss (RL) of loop antennas 434, 444, and 454 of FIGS. 6A-6C with respect to frequency. In FIG. 7, the combined bandwidth of the loop antennas 240 can include a frequency range where the return loss is lower than −10 dB, which is labelled “BW₁” and is about 105 MHz. Compared with FIG. 3, the bandwidth is widened by 40%. Also, the combined resonant frequency of the loop antennas is at 2.4 GHz, which is the same as in FIG. 3. However, the return loss at the resonant frequency, labelled “RLₘᵢₙ₁” in FIG. 7, is at −30 dB, which represents a 15 dB improvement over FIG. 3. The reduced return loss can be attributed to the improved impedance matching between the feed line (and the combined impedance of the loop antennas) and metal segment 436 (and transceiver circuit 160) provided by, for example, metal subsegment extensions 602 and 612, separation areas 430c, 440c, and 450c, and impedance matching circuit 104.

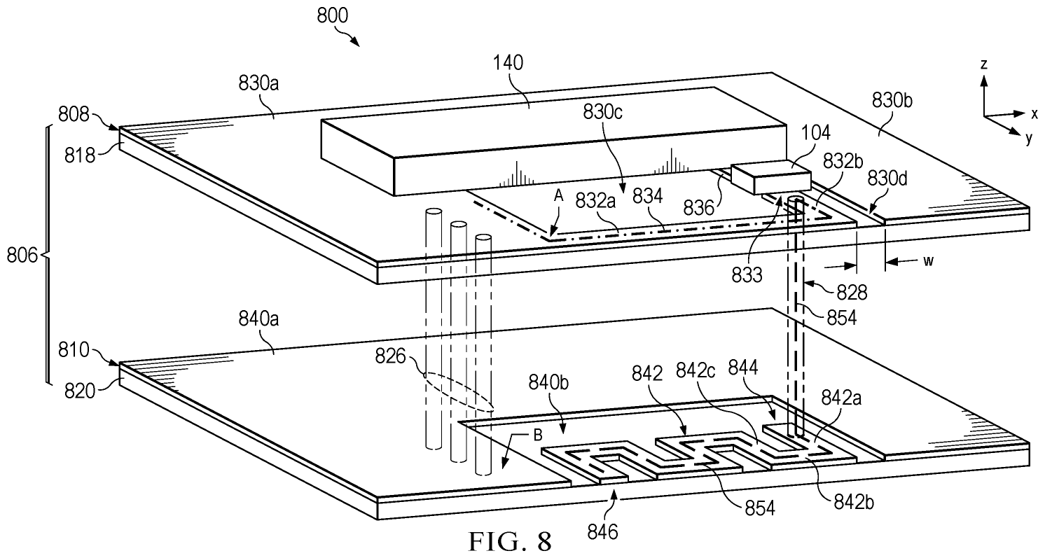

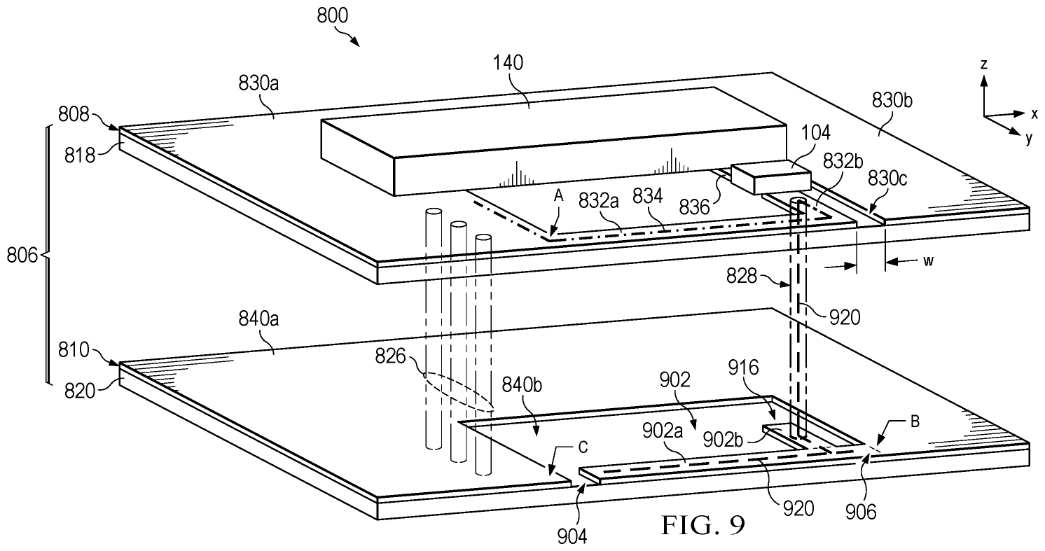

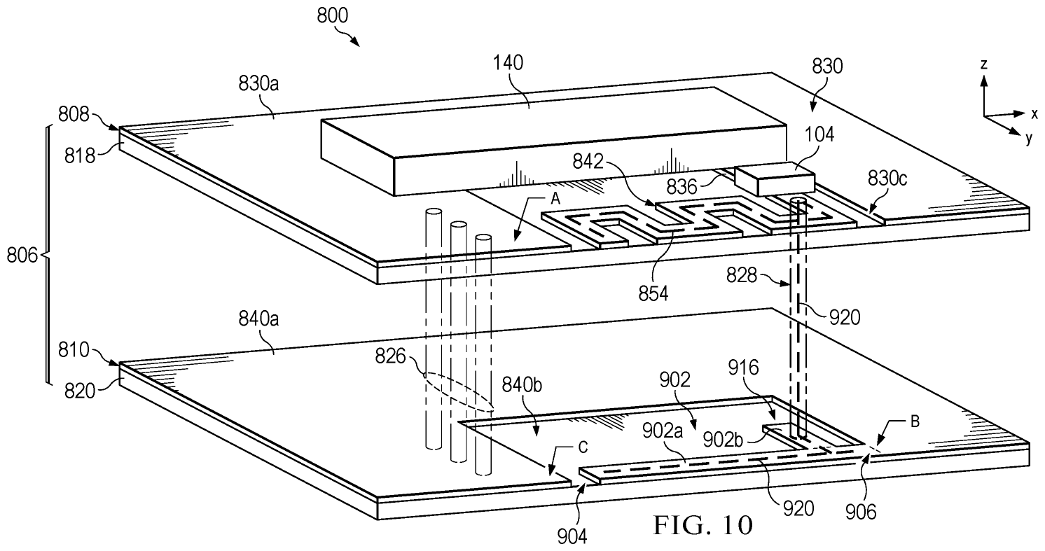

FIG. 8, FIG. 9, and FIG. 10 are schematics of example wireless systems including multi-band antennas in a multi-layer substrate. Each of FIG. 8, FIG. 9, and FIG. 10 is a schematic that illustrates a perspective and exploded view of an example wireless system 800. Referring to FIGS. 8 through 10, wireless system 800 can include semiconductor die 102 (not shown in FIGS. 8 through 10) and impedance matching circuit 104 mounted on a substrate 806, with at least semiconductor die 102 encapsulated in encapsulation package 140. Substrate 806 can include multiple metal layers, such as metal layers 808 and 810. Substrate 806 can also include dielectric layers 818 and 820. The metal layers and dielectric layers can be laminated together forming a laminated substrate. In some examples, substrate 806 may also include other metal layers and dielectric layers (not shown in FIG. 8) between metal layers 408 and 810. Substrate 806 can also include through-vias 826 and 828 that penetrate through the multiple metal layers and dielectric layers, to provide electrical connection among the multiple metal layers. In some examples, substrate 806 can include a multi-layer PCB, the metal layers can include copper layers, and the dielectric layers can include an epoxy material. In some examples, substrate 806 can include multiple PCBs laminated together, where metal layer 408 and dielectric layer 418 can be of a first PCB, and metal layer 810 and dielectric layer 820 can be of a second PCB, and the PCBs can be stacked to form a laminated substrate 806.

Each metal layer can include a metal plane and a metal segment, with the metal segment can be configured as an antenna. Wireless system 800 may include antennas of different topologies and having different operation frequency bands in different metal layers. For example, referring to FIG. 8, metal layer 808 can include a metal plane 830, which can include plane regions 830a and 830b, and a separation area 830c between plane regions 830a and 830b that exposes dielectric layer 818. Separation area 830c can be filled with an insulation material, such as dielectric and air. Metal plane 830 can be coupled to a voltage source and configured as a ground plane. Metal layer 808 can also include metal segment 832, which can include a metal subsegment 832a that extends from a part of plane region 830a (labelled “A” in FIG. 8). Metal subsegment 832b can extend from and is angled relative to metal subsegment 832a, and metal subsegment 832b can have an end 833 coupled to impedance matching circuit 104. Through-via 828 extends through metal subsegment 832b and is more proximate to end 833 than to metal subsegment 832a. Metal segment 832 can provide a loop antenna 834, which is spaced from encapsulation package 140 by separation area 830c, and spaced from plane region 830b by a gap 830d. Gap 830d can be filled with an insulation material, such as dielectric and air. Metal layer 808 can also include a metal segment 836 coupled between impedance matching circuit 104 and semiconductor die 102.

Also, referring to FIG. 8, metal layer 810 can include a metal plane 840a and a separation area 840b. Separation area 840b can be in an external region adjacent to encapsulation package 140. Separation area 840b can be filled with an insulation material, such as dielectric and air. Metal plane 840a can be coupled to metal plane 830 by through-vias 826 and can be configured as a ground plane. Metal layer 810 can also include a metal segment 842 spaced from encapsulation package 140 and plane region 840a by separation area 840b, with opposite ends 844 and 846 of metal segment 842 separated/detached from metal plane 840a. End 846 can be an open end. Through-via 828 extends through metal segments 832 and 842 and is more proximate to end 844 than end 846. Metal segment 842 can include multiple subsegments connected together, where adjacent subsegments (e.g., 842a and 842b, 842b and 842c) are angled (e.g., 90 degrees) from each other. Metal segment 842, together with through-via 828 between metal layers 808 and 810, can form a meander antenna 854. Meander antenna 854 can conduct a current through metal segment 842 and through through-via 428 between metal layers 808 and 810 to reach impedance matching circuit 104 and semiconductor die 102 in response to detecting an RF signal, or to transmit an RF signal. In some examples, metal layer 810 can include a metal subsegment extension (not shown in FIGS. 8-10) that extends from end 844 to provide additional capacitive loading for capacitive tuning of the impedance of antenna 854, as described above in FIGS. 6A-6C.

FIG. 9 and FIG. 10 illustrate additional examples of wireless system 800. In FIG. 9, metal layer 810 can include a metal segment 902 in separation area 840b, and metal segment 902 can be in an external region adjacent to encapsulation package 140. Metal segment 902 can include a metal subsegment 902a and a metal subsegment 902b. Metal subsegment 902a can extend from a first part of plane region 840a (e.g., labelled “B” in FIG. 9) and have an end 904 separated/detached from a second part of plane region 840a (labelled “C” in FIG. 9). End 904 can be an open/disconnected end. Also, metal subsegment 902b can extend from and is angled relative to metal subsegment 902a, and metal subsegment 902b can have an end 916 detached/separated from metal plane 840a to form an open/disconnected end. Metal subsegment 902b can be more proximate to ground plane 840a than to end 904. Through-via 828 extends through metal subsegment 902b to provide electrical connection between metal segments 832 and 902, and is more proximate to end 916 than to metal subsegment 902a. Metal segment 902, together with through-via 828 between metal layers 808 and 810, can form an inverted-F antenna 920. Also, in FIG. 10, wireless system 800 can include metal layer 808 including metal segment 842 that provides meander antenna 854, and metal layer 810 including metal segment 902 that provides inverted-F antenna 920. In FIG. 9 and FIG. 10, metal layer 810 can include a metal subsegment extension (not shown in FIG. 10) that extends from end 916 of metal subsegment 902b to provide additional capacitive loading for capacitive tuning of the impedance of antenna 920.

In some examples, metal layer 808 can also include metal segment 902 to provide inverted-F antenna 920 where impedance matching circuit 104 can be coupled to end 916 of metal subsegment 902b, and metal layer 810 can include metal segment 842 to provide meander antenna 854.

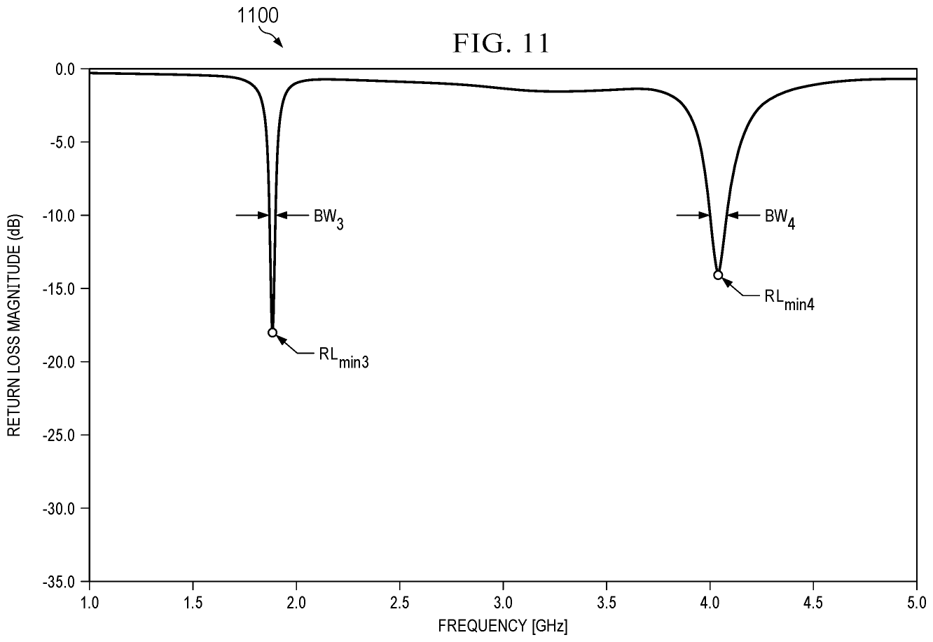

FIG. 11 is a graph 1100 of the variation of the combined return loss (RL) of multi-band antennas of FIGS. 8-10. Referring to FIG. 11, the multi-band antennas can have two non-overlapping operation frequency ranges. The first operation frequency range can center around 1.9 GHz and have a bandwidth labelled BW₃, and the second operation frequency range can center around 4.1 GHz and have a bandwidth labelled BW₄, where a first antenna of the multi-band antennas can have a first resonant frequency at 1.9 GHz and a second antenna of the multi-band antennas can have a second resonant frequency at 4.1 GHz. The return loss at the first resonant frequency of 1.9 GHz can be at −18 dB (labelled “RLₘᵢₙ₃”), and the return loss at the second resonant frequency of 4.1 GHz can be at −14 dB (labelled “RLₘᵢₙ₄”).

The techniques described above can be used to implement various antenna types, including omnidirectional and non-omnidirectional antennas, in a multi-layer substrate. Examples of omnidirectional antennas can include a loop antenna and a meander antenna, such as loop antenna 834 and meander antenna 854 of FIGS. 8-10. Examples of non-omnidirectional antennas can include a patch antenna, a Vivaldi antenna, a multi-layer helical antenna, and a horn antenna.

In this description, the term “couple” may cover connections, communications or signal paths that enable a functional relationship consistent with this description. For example, if device A provides a signal to control device B to perform an action, then: (a) in a first example, device A is directly electrically coupled to device B; or (b) in a second example, device A is indirectly electrically coupled to device B through intervening component C if intervening component C does not substantially alter the functional relationship between device A and device B, so device B is controlled by device A via the control signal provided by device A.

In this description, a device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be adapted to be electrically coupled to those components to form the described circuitry or device. For example, a structure described herein as including one or more semiconductor elements (such as transistors), one or more passive elements (such as resistors, capacitors and/or inductors), and/or one or more sources (such as voltage and/or current sources) may instead include only the semiconductor elements within a single physical device (e.g., a semiconductor die and/or integrated circuit (IC) package) and may be adapted to be electrically coupled to at least some of the passive elements and/or the sources to form the described structure either at a time of manufacture or after a time of manufacture, such as by an end-user and/or a third party.

While certain components may be described herein as being of a particular process technology, these components may be exchanged for components of other process technologies. Circuits described herein are reconfigurable to include the replaced components to provide functionality at least partially similar to functionality available before the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in series or in parallel between the same two nodes as the single resistor or capacitor.

Uses of the phrase “ground voltage potential” in this description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter.

Modifications are possible in the described examples, and other examples are possible, within the scope of the claims.

What is claimed is:

1. An apparatus comprising:
an integrated circuit;
a first metal layer including a first antenna connected to the integrated circuit, the first antenna being in a first region, the first region being external to the integrated circuit;
a second metal layer including a second antenna in a second region external to the integrated circuit;
a substrate between the first and second metal layers, in which the substrate and the first and second metal layers form a laminate; and
a through-via in the substrate that couples between the first and second antennas.

2. The apparatus of claim 1, wherein:
the first metal layer includes a first metal segment spaced from the integrated circuit by a first area;
the second metal layer includes: a second metal segment spaced from the integrated circuit by a second area
the first metal segment forms the first antenna;
the second metal segment forms the second antenna; and
the through-via extends through the first and second metal segments.

3. The apparatus of claim 2, wherein the first metal layer includes a first ground plane, and the second metal layer includes a second ground plane.

4. The apparatus of claim 3, wherein:
the first metal segment includes a first metal subsegment and a second metal subsegment;
the first metal subsegment extends from the first ground plane;
the second metal subsegment extends from an end of the first metal subsegment and is angled relative to the first metal subsegment;
the second metal subsegment has an end detached from the first ground plane; and
the through-via extends through the second metal subsegment and is more proximate to the end of the second metal subsegment than to the first metal subsegment.

5. The apparatus of claim 4, wherein:
the second metal segment includes a third metal subsegment and a fourth metal subsegment;
the third metal subsegment extends from the second ground plane;
the fourth metal subsegment extends from an end of the third metal subsegment and is angled relative to the third metal subsegment;
the fourth metal subsegment has an end detached from the second ground plane; and
the through-via extends through the fourth metal subsegment and is more proximate to the end of the fourth metal subsegment than to the third metal subsegment.

6. The apparatus of claim 5, wherein the second metal segment has a fifth metal subsegment that extends from an end of the fourth metal subsegment that is more proximate to the through-via than to the third metal subsegment, the fifth metal subsegment having an end detached from the second ground plane.

7. The apparatus of claim 6, wherein the integrated circuit has a transceiver circuit coupled to the first metal segment; and
wherein a length of the fifth metal subsegment is based on an impedance of the transceiver circuit.

8. The apparatus of claim 5, wherein the first and second metal subsegments form a first loop antenna as the first antenna, and the third and fourth metal subsegments are form a second loop antenna as the second antenna.

9. The apparatus of claim 8, wherein:
the first loop antenna is configured to have a first resonant frequency and a first bandwidth, and the second loop antenna is configured to have a second resonant frequency and a second bandwidth, such that the first and second loop antennas have a combined bandwidth wider than each of the first and second bandwidths.

10. The apparatus of claim 9, wherein the first loop antenna and the second loop antenna have different loop sizes.

11. The apparatus of claim 9, wherein the first metal segment and the second metal segment have different widths.

12. The apparatus of claim 3, wherein the first metal segment has opposite first and second ends, and the first end and the second end are detached from the first ground plane.

13. The apparatus of claim 12, wherein the first metal segment includes a meander metal segment.

14. The apparatus of claim 3, wherein:
the first metal segment includes a first metal subsegment and a second metal subsegment;
the first metal subsegment extends from the first ground plane and has an end detached from the first ground plane;
the second metal subsegment extends from and is angled relative to the first metal sub segment;
the second metal subsegment is more proximate to the first ground plane than the end of the first metal subsegment; and
the through-via extends through the second metal subsegment and is more proximate to the end of the second metal subsegment than the first metal subsegment.

15. The apparatus of claim 14, wherein the first metal segment is part of an inverted F antenna.

16. The apparatus of claim 2, further comprising an impedance matching circuit coupled between the integrated circuit and the first metal segment.

17. The apparatus of claim 16, wherein the impedance matching circuit includes a capacitor coupled between the integrated circuit and the first metal segment.

18. The apparatus of claim 1, wherein the integrated circuit includes a package coated with a metal layer.

19. The apparatus of claim 1, wherein substrate is part of a printed circuit board (PCB).

20. The apparatus of claim 1, wherein the first metal layer is part of a first PCB, and the second metal layer is part of a second PCB.
